(19) United States
(12) Patent Application Publication
(10) Pub. No.: US 2024/0210499 A1
(43) Pub. Date: Jun. 27, 2024

(54) METHOD AND APPARATUS FOR MAPPING THE OPEN CIRCUIT DEMAGNETISATION CURVE OF A SAMPLE OF MAGNETIC MATERIAL TO A CLOSED CIRCUIT DEMAGNETISATION CURVE

(71) Applicants: James CLEEWTT, Falmouth, Cornwall (GB); Robin CORNELIUS, Falmouth, Cornwall (GB); Jack WADE, Falmouth, Cornwall (GB)

(72) Inventors: James CLEWETT, Falmouth, Cornwall (GB); Robin CORNELIUS, Falmouth, Cornwall (GB); Jack WADE, Falmouth, Cornwall (GB)

(21) Appl. No.: 18/288,395

(22) PCT Filed: Apr. 26, 2022
(86) PCT No.: PCT/IB2022/053868

§ 371 Date: Oct. 26, 2023

(30) Foreign Application Priority Data
Apr. 27, 2021 (GB) 2105993.6

(51) Int. Cl. G01R 33/14

(52) U.S. Cl. CPC G01R 33/14

(57) ABSTRACT

A method and apparatus for accurately mapping the closed magnetic circuit demagnetisation curve to and from a open magnetic circuit demagnetisation curve. The method utilises open circuit data from a pulsed field magnetometer (PFM) and computer modelling of both the PFM (open circuit) and permeameter (closed circuit) apparatus. This method is more accurate than previous methods and can calculate the closed circuit curve within the precision of both the PFM and the permeameter apparatus.

### TECHNICAL FIELD OF THE INVENTION

This invention relates to the calculation of a closed magnetic circuit demagnetisation curve based on open magnetic circuit data measured in a sample of magnetic material.

### BACKGROUND

There are many circumstances in which it is important to know the magnetisation of a material in response to an externally applied magnetic field; contemporary examples include the manufacture of parts for use in electric vehicle motors, wind turbine generators and electrical steel for transformers.

Magnetic materials are characterised and graded by their hysteresis loop [Bertotti 1998]. The second quadrant of the hysteresis loop, where the applied field is in opposition to the sample magnetisation, is called the demagnetisation curve and is of particular interest because this is where most magnetic machines operate. Demagnetisation curves are traditionally measured in a closed magnetic circuit using a permeameter [TR 60404-5 2015]. The permeameter applies a highly uniform magnetic field, and additionally reduces finite size effects in the sample. Permeameter measurements are performed relatively slowly, over approximately 60 seconds, such that the measurement is quasi-static with respect to the time scales relevant to the magnetic physics in the sample. As such, demagnetisation curves measured in this way have long been regarded as the ‘gold standard’, and are often (mistakenly) believed to be an immutable material property.

Modern rare-earth, hard magnetic materials, such as samarium cobalt and neodymium require large saturation and coercive fields that will saturate the steel core of a permeameter, and in doing so corrupt the measurement [Cornelius 2005]. For this reason it is necessary to characterise rare-earth materials in an open magnetic circuit, for example by using a pulsed field magnetometer (PFM) [TR 62331 2005], a vibrating sample magnetometer (VSM) or vibrating coil magnetometer (VCM).

Demagnetisation curves measured in an open magnetic circuit differ from closed magnetic circuit measurements due to self demagnetisation field effects [Chen 1991]. Pulsed field measurements use high frequency magnetisation pulses that additionally induce eddy currents in the system, introducing a distortion in the measured characteristic that is strongly dependent on the sweep rate of the external field [Grossinger 2002]. Subsequently, the open magnetic circuit demagnetisation curve is a function of the measurement protocol, and the sample geometry, it is not an immutable material property.

Nonetheless, PFM measurements are of great interest because they benefit from being an order or magnitude cheaper than VSM or VCM methods, and are much faster and more reproducible than closed magnetic circuit permeameter measurements.

A number of mathematical techniques are available to map open magnetic circuit demagnetisation curves onto a closed magnetic circuit curves. However, these methods remain somewhat inaccurate. Typically the important ‘knee’ region of the curve can differ by 5 to 10%, although the precision (repeatability) of permeameter and PFM measurements is typically better than +/−1%.

The present invention seeks to provide a new and more accurate way of mapping the two curves to each other.

### SUMMARY OF THE INVENTION

When viewed from one aspect the present invention proposes a method of mapping the open circuit demagnetisation curve of a sample of magnetic material to a closed circuit demagnetisation curve. The method may comprise the following steps:
(i) measure the open circuit demagnetisation curve of the sample using pulsed field magnetometry;
(ii) remove from the demagnetisation curve linear eddy current effects due to the applied field sweep rate;
(iii) remove from the demagnetisation curve non-linear eddy current effects due to the sample demagnetisation;
(iv) remove the effects of sample geometry from the demagnetisation curve;
(v) add to the demagnetisation curve the effects of an idealised steel permeameter core.

The method may be performed by pulsed field magnetometry apparatus.

### DETAILED DESCRIPTION OF THE INVENTION

The present invention is based on a recognition, for the first time, that the physics relating open and closed magnetic circuit demagnetisation curves resides not only in the sample being measured, but also in the interaction of the sample with the steel core of a permeameter as used for closed circuit measurements. It is therefore proposed that, for increased accuracy, the mapping becomes a multi-stage process described below.
(i) Measure the open magnetic circuit demagnetisation curve of a sample using pulsed field magnetometry.
(ii) Use a procedure such as the ones described below to remove from the demagnetisation curve linear eddy current effects, where they exist, due to the applied field sweep rate.
(iii) Use a procedure such as the one described below to remove from the demagnetisation curve non-linear eddy current effects, where they exist, due to the sample demagnetisation.
(iv) Remove the effects of sample geometry from the demagnetisation curve using a self demagnetisation field factor (a mathematical skew) or another suitable method.
(v) Use a procedure such as the one described below to add to the demagnetisation curve the effects of an idealised steel core.

The use of pulsed field magnetometry to measure the open magnetic circuit demagnetisation curve of a sample is known. [Hirst Magnetic Instruments Limited patent.]

Other procedures which may be used in the method will now be described.

### Removing the Effects of Linear Eddy Currents—Step (ii)

Either of two methods may be used to remove the linear eddy current effects, a perturbative method, and a single pulse method.

### Perturbative Method

In contrast to quasi-static measurement methods, the high frequency, pulsed applied field, H, used in a PFM will induce eddy currents in the system. For the frequency ranges used by a PFM, the eddy currents vary linearly with the applied frequency. As such a perturbative method can be used to calculate, and thus remove the effects of the eddy current from the measurement.

Two demagnetisation curves are measured at different frequencies. To reduce the impact of noise it is important that the two frequencies are sufficiently separated, conversely to avoid the effects of non-linearities the frequencies should not be too different. Typically a PFM uses frequencies of f₁˜100 Hz and f₂=2f₁.

Increasing the frequency of the pulse results in a shift of the effective applied field along the load line. For this reason, the perturbative calculation is carried out along the length of all load lines. The perturbation in the length of the load line, l, is δl, due to a frequency shift of f₁−f₂=δf.

In order to calculate the quasi-static demagnetisation curve, the shift in the frequency must be f₁−0=Δf. As such, a correction of Δl=(δl/δf). Δf is required, where Δl is the difference between the demagnetisation curve measured at f=f₁, and the quasi-static demagnetisation curve calculated for f=0 Hz.

The linearity of the perturbative method ensures that any close pair of f₁ and f₂ pulses will predict the same quasi-static demagnetisation curve.

### Single Pulse Method

Single pulse eddy correction takes advantage of the phase shift in the magnetic field due to the induced eddy currents with respect to the driving field. The induced field lags Π/2 behind the driving field. As such, the pick-up coil measures a small but distinctive sinusoidally varying field superimposed on the changing magnetisation of the sample. By curve-fitting the sinusoid it is straight-forward to parameterize and hence remove the field due to the eddy current.

The single pulse method has two principal advantages over the perturbative method. Firstly it allows the quasi-static prediction to be made from a single pulse, which is quicker and uses less energy than a two-pulse method. Secondly it naturally captures any systematic errors due to unanticipated current loops outwith the sample magnet.

Removing the Effects of the Demagnetisation Rate in the Measured Sample—Step (iii)

As the applied field approaches the coercive field for the sample being measured, the sample begins to demagnetise. In a PFM the demagnetisation takes place in approximately 1 millisecond. This gives rise to a rate-dependent eddy current that varies in proportion to −dJ/dt, where J is the instantaneous magnetic moment of the sample, and t is time. The eddy current is further filtered by capacitive and inductive coupling to both the sample and the magnetising core.

The eddy current creates a proportional magnetic flux, henceforth the eddy flux.

In order to match with a quasi-static measurement of a demagnetisation curve, this time-dependent flux must be removed from the signal. It is necessary to calculate the eddy current and also the magnetic coupling between the eddy flux and the PFM pick-up coil.

Finally the appropriate amount of eddy-flux can be subtracted from the measured demagnetisation curve.

### Add the Effects of an Idealised Steel Core—Step (v)

In a permeameter both the magnitude of the sample dipole moment, J, and the relative permeability of the sample being measured result in a divergence of the magnetisation in the steel core, H. These effects are strongly coupled. Numerical methods or otherwise are used to calculate the relationship between the field that is actually applied to the sample, and the measured applied field in the permeameter air gap.

The numerical methods model either an idealised steel, or steel-cobalt core. It can be shown that the precise details of the steel have only a small effect with respect to the total correction that is calculated for the applied field.

It is necessary to calculate the measured field for all applied fields and all sample dipole moments. This provides the proper calibration for the applied field.

This proper calibration is a key element to obtain an accurate mapping between open magnetic circuit demagnetisation curves and closed magnetic circuit demagnetisation curves.

The invention thus provides a way to extend the accuracy of the open to closed magnetic circuit mapping (and vice versa) to within the precision (repeatability) of the permeameter and PFM measurements, which is better than +/−1%.

Whilst the above description places emphasis on the areas which are believed to be new and addresses specific problems which have been identified, it is intended that the features disclosed herein may be used in any combination which is capable of providing a new and useful advance in the art.

### REFERENCES

[Bertotti 1998] Hystersis in Magnetism. Academic Press, 1998.
[TR 60404-5 2015] Permanent magnet (magnetically hard) materials—methods of measurement of magnetic properties. IEC TC/86 WG5, 2015.
[Cornelius 2005] Pulsed Field Magnetometry for High-Speed Characterisation of Rare-Earth Magnets. 2005.
[TR 62331 2005] Pulsed Field Magnetometry. IEC TC/86 WG5, 2005.
[Chen 1991] Demagnetizing factors for cylinders, IEEE Trans. 1991.
[Grossinger 2002] Eddy currents in pulsed field measurements, Proc. Joint Europen Magnetic Symposia, 2002.
[Hirst Magnetic Instruments Limited patent] EP 0 672 261-B1.

1. A method of mapping the open circuit demagnetisation curve of a sample of magnetic material to a closed circuit demagnetisation curve:
(i) measure the open circuit demagnetisation curve of the sample using pulsed field magnetometry;
(ii) remove from the demagnetisation curve linear eddy current effects due to the applied field sweep rate;
(iii) remove from the demagnetisation curve non-linear eddy current effects due to the sample demagnetisation;
(iv) remove the effects of sample geometry from the demagnetisation curve;
(v) add to the demagnetisation curve the effects of an idealised steel permeameter core.

2. A method according to claim 1 wherein linear eddy current effects due to the applied field sweep rate are removed from the demagnetisation curve using a perturbative method.

3. A method according to claim 1 wherein linear eddy current effects due to the applied field sweep rate are removed from the demagnetisation curve using a single pulse method.

4. A method according to claim 1 wherein non-linear eddy current effects due to the sample demagnetisation are removed from the demagnetisation curve using the eddy current and the magnetic coupling between the eddy flux and a PFM pick-up coil.

5. A method according to claim 1 wherein the effects of an idealised steel permeameter core which are added to the demagnetisation curve are obtained by calculating the relationship between the field that is actually applied to the sample and the measured applied field in a permeameter air gap.

6. A method according to claim 5 wherein the effects of an idealised steel permeameter core which are added to the demagnetisation curve are obtained by calculating the measured field for all applied fields and all sample dipole moments.

7. Apparatus for mapping the open circuit demagnetisation curve of a sample of magnetic material to a closed circuit demagnetisation curve:
(i) means to measure the open circuit demagnetisation curve of the sample using pulsed field magnetometry;
(ii) means to remove from the demagnetisation curve linear eddy current effects due to the applied field sweep rate;
(iii) means to remove from the demagnetisation curve non-linear eddy current effects due to the sample demagnetisation;
(iv) means to remove the effects of sample geometry from the demagnetisation curve;
(v) means to add to the demagnetisation curve the effects of an idealised steel permeameter core.

8. A method according to claim 7 wherein said means to remove from the demagnetisation curve linear eddy current effects due to the applied field sweep rate uses a perturbative method.

9. A method according to claim 8 wherein said means to remove from the demagnetisation curve linear eddy current effects due to the applied field sweep rate uses a single pulse method.

10. A method according to claim 7 wherein said means to remove from the demagnetisation curve non-linear eddy current effects due to the sample demagnetisation use the eddy current and the magnetic coupling between the eddy flux and a PFM pick-up coil.

11. A method according to claim 7 wherein said means to add to the demagnetisation curve the effects of an idealised steel permeameter core uses the relationship between the field that is actually applied to the sample and the measured applied field in a permeameter air gap.

12. A method according to claim 11 wherein said means to add to the demagnetisation curve the effects of an idealised steel permeameter core uses the measured field for all applied fields and all sample dipole moments.
